(19) United States
(12) Patent Application Publication
(10) Pub. No.: US 2015/0205208 A1
(43) Pub. Date: Jul. 23, 2015

(54) DEVELOPER COMPOSITION

(71) Applicants: BOE TECHNOLOGY GROUP CO., LTD., Beijing (CN); BEIJING BOE DISPLAY TECHNOLOGY CO., LTD., Beijing (CN)

(72) Inventors: Tonghua Yang, Beijing (CN); Hongjiang Wu, Beijing (CN); Min Li, Beijing (CN); Jikai Zhang, Beijing (CN)

(21) Appl. No.: 14/351,740

(22) PCT Filed: Dec. 10, 2013
(86) PCT No.: PCT/CN2013/088944

§ 371 Date: Apr. 14, 2014

(30) Foreign Application Priority Data
May 24, 2013 (CN) 201310198744.4

(51) Int. Cl. G03F 7/32

(52) U.S. Cl. CPC G03F 7/32

(57) ABSTRACT

A developer composition including 0.01 to 5.0 parts by weight of inorganic or organic acids, 0.01 to 5.0 parts by weight of surfactant, 0.1 to 10.0 parts by weight of water-soluble organic solvent, 85 to 99 parts by weight of water, and 0 to 2 parts by weight of additives, based on 100 parts by weight of the developer composition.

### INVENTION FIELD

An embodiment of the present invention relates to a developer composition for developing color filters.

### BACKGROUND

Color filters are optical filter exhibiting colors. They can precisely selectively transmit light within a narrow range of wavelengths, and reflect light within other undesired wavelengths. Color filters are generally positioned at the front of a light source, so that the eyes of customers can receive saturated light of a certain color. Currently, there are red, green, blue color filters, etc.

The developer composition used in color filters are commonly basic developer compositions, including inorganic basic developer composition, such as, carbonates or potassium hydroxides; and organic basic developer composition, such as, tetramethylammonium hydroxides. Basic developer compositions are widely used due to its good developing properties for photoresists. Over the development of liquid display, high brilliance and high transmission become more important. For satisfying these performance indice, the pigment particles in the photoresists should have to become finer. However, it is well known that the smaller the pigment particles, the more complicated the process for dispersing the particles, and the incorporation of basic hyperdispersants can improve effectively the dispersing stability of particles, e.g., as described in CN101403858. It will result in that the produced photoresists show deteriorated resolution in the basic developer composition and are unlikely to form the designed patterns. Moreover, inorganic basic developer composition may remain in the photoresist layer due to the presence of metal ions including Na⁺, K⁺, etc., which is likely to contaminating the liquid crystal and causing the occurrence of defects, such as, image retention.

### SUMMARY OF INVENTION

To address the aforesaid problems, an embodiment of the present invention provides a developer composition comprising: based on 100 parts by weight of the developer composition,

| | |
|---|---|
| inorganic or organic acid | 0.01 to 5.0 parts by weight, |
| surfactant | 0.01 to 5.0 parts by weight, |
| water-soluble organic solvent | 0.1 to 10.0 parts by weight, |
| water | 85 to 99 parts by weight, and |
| additives | 0 to 2 parts by weight. |

In one aspect, the inorganic acid may be is one or more selected from the group consisting of hydrochloric acid, sulfuric acid, nitric acid, phosphoric acid, carbonic acid and boric acid; and the organic acid may be one or more selected from the group consisting of formic acid, acetic acid, propionic acid, benzoic acid, oxalic acid, malonic acid, succinic acid, adipic acid, itaconic acid, citraconic acid, and fumaric acid.

In another aspect, the surfactant may be cationic surfactant, anionic surfactant or nonionic surfactant. The cationic surfactant may be primary amine salt, secondary amine salt, tertiary amine salt, or quaternary ammonium salt. The anionic surfactant may be carboxylates, sulfonates, sulfates or phosphates. The nonionic surfactant may be polyoxyethylenes, polyols, polyethers, or alkanolamides.

In yet another aspect, the water-soluble organic solvent may be one or more selected from the group consisting of methanol, ethanol, propanol, ethylene glycol, propylene glycol, isopropanol, N,N-dimethylformamide, N,N-dimethylacetamide, acetone, N-methylpyrrolidone and N-ethylpyrrolidone.

In still another aspect, the water is deionized water.

In still yet another aspect, the additives comprise at least one of defoamer and stabilizer.

### DETAILED DESCRIPTION OF INVENTION

For further clarifying the objects, technical solutions, and advantages of the present invention, the following examples are provided to illustrate the present invention in details.

The developer composition according to an embodiment of the present invention comprises based on 100 parts by weight of the developer composition,

| | |
|---|---|
| inorganic or organic acid | 0.01 to 5.0 parts by weight, |
| surfactant | 0.01 to 5.0 parts by weight, |
| water-soluble organic solvent | 0.1 to 10.0 parts by weight, |
| water | 85 to 99 parts by weight, and |
| additives | 0 to 2 parts by weight. |

In one aspect of the present invention, the inorganic acid may be one or more selected from the group consisting of hydrochloric acid, sulfuric acid, nitric acid, phosphoric acid, carbonic acid and boric acid; and the organic acid may be one or more selected from the group consisting of formic acid, acetic acid, propionic acid, benzoic acid, oxalic acid, malonic acid, succinic acid, adipic acid, itaconic acid, citraconic acid, and fumaric acid.

The inorganic or organic acids impart an acidic property to the developer composition according to the embodiment of the present invention. If the amount of the inorganic or organic acid is less than 0.01 part by weight, the developer composition exhibits a relatively high pH value and insufficient developing ability; and if the amount of inorganic or organic acid is greater than 5.0 parts by weight, the developer composition exhibits a relatively high pH value and may corrade the film surface.

In another aspect, the surfactant may be primary amine salts, secondary amine salts, tertiary amine salts, or quaternary ammonium salts (e.g., lauryldimethylbenzylammonium chloride, stearyldimethylbenzylammonium chloride, cetyltrimethylammonium chloride(bromide))-based cationic surfactant; or the surfactant may be carboxylates, sulfonates, sulfates or phosphates anionic surfactant; or the surfactant may be polyoxyethylenes, polyols, polyethers, or alkanolamides-based nonionic surfactant; or the surfactant may be any combination of the aforesaid surfactants.

The surfactant imparts good wettability and solubility to the developer composition according to the embodiment of the present invention, and can improve effectively the developing linearity. If the amount of the surfactant is less than 0.01 part by weight, the developer composition exhibits insufficient wettability and deteriorated developing linearity; and if the amount of surfactant is greater than 5 parts by weight, the surfactant is unlikely to dissolve in the developer composition and tends to separate out, so as to cause the waste of cost.

In another aspect, the water-soluble organic solvent may be one or more selected from the group consisting of methanol, ethanol, propanol, ethylene glycol, propylene glycol, isopropanol, N,N-dimethylfoimamide, N,N-dimethylacetamide, acetone, N-methylpyrrolidone and N-ethylpyrrolidone.

The water-soluble organic solvent imparts good wettability and solubility to the developer composition according to the embodiment of the present invention, and can enhance effectively the solubility of the surfactant in the developer composition. If the amount of the water-soluble organic solvent is less than 0.1 parts by weight, the surfactant is unlikely to dissolving in the developer composition and exhibits insufficient wetting ability; and if the amount of water-soluble organic solvent is greater than 10.0 parts by weight, the cost will be increased and the composition is not environmentally friendly.

In another aspect, the water is deionized water.

In yet another aspect, the additives comprise at least one of defoamer and stabilizer.

The object of adding additives is to impart good stability to the developer composition according to the embodiment of the present invention.

The developer composition according to the embodiment of the present invention is an acidic developer composition, and can address the problem that the pigment particles in the photoresists are unlikely to developing in a basic developer composition caused by the incorporation of hyperdispersants during fming of the particles, thereby satisfying the requirements of good resolution and refined patterns. Moreover, the developer composition according to the embodiment of the present invention is an acidic, metal ion-free developer composition, thereby avoiding the problem that the liquid crystal is contaminated by metal ions (such as, Na⁺, K⁺, etc.) residua in a basic developer composition, and preventing effectively from image retention in a liquid crystal panel.

Hereinafter the developer composition according to the embodiments of the present invention is described in details, with reference to the examples.

### EXAMPLE 1

0.3 parts by weight of hydrochloric acid, 0.5 parts by weight of sodium lauryl sulfate, 5 parts by weight of ethanol, and 0.01 part by weight of defoamer were added into 94.19 parts by weight of deionized water, stirred homogenously to produce a developer composition 1.

### EXAMPLE 2

0.3 parts by weight of hydrochloric acid, 1.0 parts by weight of lauryldimethylbenzylammonium chloride, 6 parts by weight of N-methylpyrrolidone, and 0.01 part by weight of defoamer were added into 92.69 parts by weight of deionized water, stirred homogenously to produce developer composition 2.

### EXAMPLE 3

0.3 parts by weight of dilute sulfuric acid, 0.5 parts by weight of sodium lauryl benzenesulfonate, 0.5 parts by weight ofspan20, 4 parts by weight of N,N-dimethylformamide, and 0.01 part by weight of defoamer were added into 94.69 parts by weight of deionized water, stirred homogenously to produce developer composition 3.

### EXAMPLE 4

0.4 parts by weight of dilute sulfuric acid, 1.5 parts by weight of Tween 80, 5 parts by weight of N,N-dimethylformamide, and 0.01 part by weight of defoamer were added into 93.09 parts by weight of deionized water, stirred homogenously to produce developer composition 4.

### EXAMPLE 5

0.01 part by weight of hydrochloric acid, 0.5 parts by weight of sodium lauryl sulfate, and 10 parts by weight of ethanol were added into 89.49 parts by weight of deionized water, stirred homogenously to produce developer composition 5.

### EXAMPLE 6

5 parts by weight of hydrochloric acid, 0.01 part by weight of sodium lauryl sulfate, and 5 parts by weight of ethanol were added into 89.99 parts by weight of deionized water, stirred homogenously to produce developer composition6.

### EXAMPLE 7

0.3 parts by weight of hydrochloric acid, 5 parts by weight of sodium lauryl benzenesulfonate, and 0.1 parts by weight of ethanol were added into 94.6 parts by weight of deionized water, stirred homogenously to produce developer composition 7 (slightly cloudy).

### EXAMPLE 8

0.4 parts by weight of malonic acid, 1 part by weight of Tween 80, 1 part by weight of Span 20, 2 parts by weight of isopropanol, and 0.02 parts by weight of defoamer were added into 95.58 parts by weight of deionized water, stirred homogenously to produce developer composition 8.

### EXAMPLE 9

1 part by weight of succinic acid, 1 part by weight of sodium lauryl sulfate, 0.5 parts by weight of Tween 80, 4 parts by weight isopropanol, and 0.03 parts by weight of defoamer were added into 93.47 parts by weight of deionized water, stirred homogenously to produce developer composition 9.

Hereinafter the advantages of the developer composition according to the embodiments of the present invention are described with reference to experimental comparison, wherein developer compositions comprising the following components are used as Comparative Examples.

### COMPARATIVE EXAMPLE 1

0.4 parts by weight of KOH and 0.5 parts by weight of sodium lauryl sulfate were added into 99.1 parts by weight of deionized water, stirred homogenously to produce comparative developer composition 1.

### COMPARATIVE EXAMPLE 2

0.3 parts by weight of sodium carbonate, 0.2 parts by weight of sodium bicarbonate, and 0.5 parts by weight of octylphenol polyoxyethylene ether were added into 99 parts by weight of deionized water, stirred homogenously to produce comparative developer composition 2.

Each of the aforesaid developer compositions was subject to developing color photoresists for test.

Various performance indice of Examples 1 to 9, Comparative Example 1, and Comparative Example 2 are listed in Table 1 as below.

TABLE 1
Various performance indice of Examples 1 to 9, Comparative
Example 1, and Comparative Example 2

| | Devel- | | Amount | | |
|---|---|---|---|---|---|
| | oping | Wetta- | of | Defoaming | Dispersing |
| | Property | bility | Residua | Property | Stability |
| developer | ⊚ | ⊚ | ⊚ | ⊚ | ⊚ |
| composition1 | | | | | |
| developer | ◯ | ⊚ | ⊚ | ⊚ | ⊚ |
| composition2 | | | | | |
| developer | ⊚ | ⊚ | ⊚ | ⊚ | ⊚ |
| composition3 | | | | | |
| developer | ⊚ | ⊚ | ⊚ | ⊚ | ⊚ |
| composition4 | | | | | |
| developer | ◯ | ⊚ | ◯ | ◯ | ◯ |
| composition5 | | | | | |
| developer | ◯ | ⊚ | ◯ | ◯ | ⊚ |
| composition6 | | | | | |
| developer | ⊚ | ⊚ | ⊚ | Δ | ⊚ |
| composition7 | | | | | |
| developer | ⊚ | ⊚ | ⊚ | ⊚ | ⊚ |
| composition8 | | | | | |
| developer | ⊚ | ⊚ | ⊚ | ⊚ | ⊚ |
| composition9 | | | | | |
| comparative | Δ | ⊚ | Δ | ◯ | ◯ |
| developer | | | | | |
| composition 1 | | | | | |
| comparative | Δ | ⊚ | Δ | ◯ | ◯ |
| developer | | | | | |
| composition 2 | | | | | |

Among others, the testing standards of each index and the meaning of each label are provided as follows:

1) Developing properties: Observing the integrality of various pixels and the regularity of pattern edges under a 200× microscope.
⊚: Good
∘: Moderate
Δ: Poor

2) Wettability: Observed the spreading of 50 mg of the developer composition onto the surface of photoresist film.
⊚: Good
∘: Moderate
Δ: Poor

3) Amount of Residua: Observe under 1000× scanning electronic microscope if there is residua in the non-pixel area of glass substrate.
⊚: No residua
∘: A few residua
Δ: Many residua

4) Defoaming property: 30 ml of developer composition was charged into a 100 ml cuvette, and shaken up and down. Then, measure the height of foams.
⊚: Less than 0.5 cm
∘: Between 0.5 cm and 1.0 cm
Δ: Greater than 1.0 cm

5) Dispersing stability: 1 g color photoresists was added into 500 ml developer composition, mixed to homogenous, and kept stand for 1 hr. The mixture was filtered with a 5-micron filter paper, and then the filter paper was dried at 100 ° C. to constant weight. Evaluation was made in accordance with the weight change of the filter paper.
⊚: Weight change of filter paper of less than 0.01 g
∘: Weight change of filter paper between 0.01 and 0.03 g
Δ: Weight change of filter paper of greater than 0.03 g

The results as shown in Table 1 indicate that the developer composition according to the embodiments of the present invention appears good in terms of developing property, wettability, amount of residua, defoaming property, and dispersing stability, and satisfy the requirements of a developer composition for producing high-fining and high-resolution color filters.

The aforesaid description is illustrative, other than limitative to the present invention. Person of ordinary skill in the art understand that many modifications, changes, or equivalences can available without departing the spirit and scope of the accompanying claims, and all of these modifications, changes, and equivalences fall within the scope of the present invention.

1. A developer composition comprising: based on 100 parts by weight of the developer composition,

| | |
|---|---|
| inorganic or organic acid | 0.01 to 5.0 parts by weight, |
| surfactant | 0.01 to 5.0 parts by weight, |
| water-soluble organic solvent | 0.1 to 10.0 parts by weight, |
| water | 85 to 99 parts by weight, and |
| additives | 0 to 2 parts by weight. |

2. The developer composition of claim 1, wherein the inorganic acid is one or more selected from the group consisting of hydrochloric acid, sulfuric acid, nitric acid, phosphoric acid, carbonic acid and boric acid; and the organic acid is one or more selected from the group consisting of formic acid, acetic acid, propionic acid, benzoic acid, oxalic acid, malonic acid, succinic acid, adipic acid, itaconic acid, citraconic acid, and fumaric acid.

3. The developer composition of claim 1, wherein the surfactant comprises at least one selected from cationic surfactant, anionic surfactant and nonionic surfactant.

4. The developer composition of claim 3, wherein the cationic surfactant is one or more selected from the group consisting of primary amine salts, secondary amine salts, tertiary amine salts, and quaternary ammonium salts.

5. The developer composition of claim 4, wherein the surfactant comprises a plurality of cationic surfactant.

6. The developer composition of claim 3, wherein the anionic surfactant is one or more selected from the group consisting of carboxylates, sulfonates, sulfate and phosphates.

7. The developer composition of claim 6, wherein the surfactant comprises a plurality of anionic surfactant.

8. The developer composition of claim 3, wherein the nonionic surfactant is one or more selected from the group consisting of polyoxyethylenes, polyols, polyethers, and alkanol amides nonionic surfactant.

9. The developer composition of claim 8, wherein the surfactant comprises a plurality of nonionic surfactant.

10. The developer composition of claim 1, wherein the water-soluble organic solvent is one or more selected from the group consisting of: methanol, ethanol, propanol, ethylene glycol, propylene glycol, isopropanol, N,N-dimethylformamide, N,N-dimethylacetaminde, acetone, N-methylpyrrolidone, and N-ethylpyrrolidone.

11. The developer composition of claim 1, wherein the water is deionized water.

12. The developer composition of claim 1, wherein the additives comprise at least one of defoamer and stabilizer.
